(19) United States
(12) Patent Application Publication
(10) Pub. No.: US 2026/0334582 A1
(43) Pub. Date: Oct. 29, 2026

(54) AEROSOL-GENERATING DEVICE COMPRISING A SENSING ASSEMBLY WITH A HEAT DISSIPATION STRUCTURE

(71) Applicant: Philip Morris Products S.A., Neuchatel (CH)

(72) Inventors: Michel BESSANT, Neuchâtel (CH); Liu LIU, Huizhou (CN); Wensi FU, Huizhou (CN)

(73) Assignee: Philip Morris Products S.A., Neuchatel (CH)

(21) Appl. No.: 19/127,443

(22) PCT Filed: Nov. 16, 2022
(86) PCT No.: PCT/CN2022/132284

§ 371 Date: May 6, 2025

(51) Int. Cl. A24F 40/53; A24F 40/20; A24F 40/51; G01N 21/31; H05B 3/03; H05K 1/02

(52) U.S. Cl. CPC A24F 40/53; A24F 40/51; G01N 21/31; H05B 3/03; H05K 1/0203; A24F 40/20

(57) ABSTRACT

An aerosol-generating device is provided, including a cavity to receive an aerosol-forming substrate and a sensing assembly to detect the substrate in the cavity; the sensing assembly including: a multilayer substrate including first and second outer layers defining respective first and second sides of the aerosol-forming substrate; an emitter to emit radiation into the cavity and provided on the first outer layer on a first portion; a sensor to measure a wavelength of a received radiation and provided on the first outer layer on a second portion; and a heat dissipating structure selected from: a metal backing layer provided on a surface of the second outer layer, and an extended end portion of the aerosol-forming substrate located adjacent the first or the second portion, the extended end portion extending at least 5 mm beyond the first or the second portion and being free of any electrically conductive tracks.

The present invention relates to an aerosol-generating device. The present invention further relates to an aerosol-generating system.

It is known to provide an aerosol-generating device for generating an inhalable vapor. Such devices may heat an aerosol-forming substrate to a temperature at which one or more components of the aerosol-forming substrate are volatilised without burning the aerosol-forming substrate. The aerosol-forming substrate may be provided as part of an aerosol-generating article. The aerosol-generating article may have a rod shape for insertion of the aerosol-generating article into a cavity, such as a heating chamber, of the aerosol-generating device. A heating assembly may be arranged in or around the heating chamber for heating the aerosol-forming substrate once the aerosol-generating article is inserted into the heating chamber of the aerosol-generating device.

Aerosol-generating devices often comprise several electronic components for allowing different functionalities of the device. Due to heat conduction away from the hot heating chamber during use, the temperature of such electronic components may rise to unfavourably high temperatures. This may be particularly severe for electronic components which require to be located in close proximity to the heating chamber and which do not tolerate very high temperatures. For example, optical components may be positioned near an opening of the heating chamber for identifying insertion of an aerosol-generating article into the heating chamber. At the same time, electronic components like optical components often may not be operated at too high temperatures.

It would thus be desirable to provide an aerosol-generating device which reduces temperature rise of electronic components during use. It would be desirable to provide an aerosol-generating device with improved heat dissipation.

According to an embodiment of the invention there is provided an aerosol-generating device. The aerosol-generating device may comprise a cavity for receiving an aerosol-forming substrate. The aerosol-generating device may comprise a sensing assembly for detecting the aerosol-forming substrate in the cavity. The sensing assembly may comprise a multilayer substrate. The multilayer substrate may comprise a first outer layer defining a first side of the substrate. The multilayer substrate may comprise a second outer layer defining a second side of the substrate. The sensing assembly may comprise an emitter configured to emit electromagnetic radiation into the cavity. The emitter may be provided on the first outer layer on a first portion of the substrate. The sensing assembly may comprise a sensor configured to measure at least one wavelength of a received electromagnetic radiation. The sensor may be provided on the first outer layer on a second portion of the substrate. The sensing assembly may comprise at least one heat dissipating structure. The heat dissipating structure may be selected from a metal backing layer provided on a surface of the second outer layer of the substrate, and an extended end portion of the substrate located adjacent the first portion or adjacent the second portion. The extended end portion may extend at least 5 millimeters beyond said first or second portion. The extended end portion may be free of any electrically conductive tracks on a surface thereof.

According to an embodiment of the invention there is provided an aerosol-generating device. The aerosol-generating device comprises a cavity for receiving an aerosol-forming substrate and a sensing assembly for detecting the aerosol-forming substrate in the cavity. The sensing assembly comprises a multilayer substrate. The multilayer substrate comprises a first outer layer defining a first side of the substrate and a second outer layer defining a second side of the substrate. The sensing assembly comprises an emitter configured to emit electromagnetic radiation into the cavity. The emitter is provided on the first outer layer on a first portion of the substrate. The sensing assembly comprises a sensor configured to measure at least one wavelength of a received electromagnetic radiation. The sensor is provided on the first outer layer on a second portion of the substrate. The sensing assembly comprises at least one heat dissipating structure. The at least one heat dissipating structure is selected from one or both of a metal backing layer and an extended end portion of the substrate. The metal backing layer is provided on a surface of the second outer layer of the substrate. The extended end portion is located adjacent the first portion or adjacent the second portion. The extended end portion extends at least 5 millimeters beyond said first or second portion. The outer surface of the extended end portion of the substrate is free of any electrically conductive tracks.

The sensing assembly may comprise the metal backing layer. The sensing assembly may comprise the extended end portion of the substrate. The sensing assembly may comprise both the metal backing layer and the extended end portion of the substrate.

By means of the sensing assembly comprising the at least one heat dissipating structure, an aerosol-generating device with reduced temperature rise of electronic components during use may be provided. By means of the sensing assembly comprising the at least one heat dissipating structure, an aerosol-generating device with improved heat dissipation may be provided.

An aerosol-generating device comprising the sensing assembly may advantageously be able to detect the presence and type of aerosol-generating substrate at least partially received in the cavity based on measurements of the at least one wavelength of the received electromagnetic radiation made by the sensor. The aerosol-forming substrate may be comprised in an aerosol-generating article that is at least partially received in the cavity. In use, the emitter may advantageously emit electromagnetic radiation into the cavity in which the aerosol-forming substrate is at least partially received. The electromagnetic radiation incident on the aerosol-forming substrate or the aerosol-generating article may undergo one of the following: absorption, reflection or transmission. The amount of absorption, reflection or transmission of the electromagnetic radiation at different wavelengths may depend on the chemical structure of the aerosol-forming substrate or article. Therefore, the chemical structure of the aerosol-forming substrate or article may affect the electromagnetic radiation received from the cavity by the sensor. Different aerosol-forming substrates or articles may have a different chemical structure and so may affect the electromagnetic radiation differently. Thus, the measurement of the received electromagnetic radiation may advantageously be used to determine the presence and type of aerosol-forming substrate received in the cavity.

Preferably, the sensor is configured to measure the intensity of the at least one wavelength of electromagnetic radiation. The measurement may comprise comparing the intensity of the at least one wavelength of electromagnetic radiation with a threshold value.

By the sensing assembly comprising the at least one heat dissipating structure of the invention, the temperature rise of the sensing assembly during use may be reduced by means of the heat dissipating functionality of the at least one heat dissipating structure.

The cavity of the aerosol-generating device may comprise an opening at a first end through which the aerosol-forming substrate may be receivable. The cavity may be configured to receive the aerosol-forming substrate along a longitudinal axis of the cavity. The longitudinal axis of the cavity may be parallel to a longitudinal axis of the aerosol-generating device.

The emitter and the sensor may be positioned at substantially the same height with respect to the longitudinal axis of the cavity. In other words, the emitter and the sensor may be positioned in a plane that is substantially perpendicular to the longitudinal axis of the cavity. The emitter and the sensor may be positioned such that the beam of electromagnetic radiation travels in a direction substantially perpendicular to the longitudinal axis of the cavity from the emitter to the sensor.

The cavity may comprise a second end opposite to the first end. The second end may comprise a base of the cavity.

The emitter and sensor may be positioned to emit and receive electromagnetic radiation to and from the cavity at a region between the first and second end of the cavity. The emitter may be positioned outside of the cavity. The sensor may be positioned outside of the cavity.

The emitter and sensor may be positioned distal to the second end of the cavity along the longitudinal axis of the cavity. The emitter and sensor may be positioned so as to emit and receive electromagnetic radiation to and from the second end of the cavity, respectively.

The sensing assembly may comprise a shielding plate configured to block electromagnetic radiation. The shielding plate may be positioned externally to the cavity. The shielding plate may be positioned externally to the cavity such that the sensor is arranged between the cavity and at least a portion of the shielding plate. The shielding plate may be positioned externally to the cavity such that the sensor is arranged between a longitudinal center axis of the cavity and at least a portion of the shielding plate. The sensor may be positioned between a first portion of the shielding plate and the cavity and the emitter may be positioned between a second portion of the shielding plate and the cavity.

The shielding plate may be positioned externally to the cavity such that at least a portion of the substrate is arranged between the cavity and at least a portion of the shielding plate. The shielding plate may be positioned externally to the cavity such that at least a portion of the substrate is arranged between a longitudinal center axis of the cavity and at least a portion of the shielding plate.

The first and second portions of the substrate may be planar. The planar first and second portions of the substrate may be non-co-planar. An angle between a normal to the planar first portion and a normal to the planar second portion of the substrate may be between 60 degrees and 100 degrees, preferably between 70 and 90 degrees, more preferably may be about 80 degrees.

The substrate comprises a first side onto which the emitter and the sensor are attached. The substrate may comprise a second side, opposite the first side, onto which the shielding plate is attached. This may advantageously be a straightforward arrangement that is simple to manufacture. The substrate may comprise one or more Printed Circuit Boards (PCBs). The substrate may be a Printed Circuit Board (PCB). The substrate may comprise more than one PCB. The substrate may comprise or consist of one or more flexible PCBs.

The substrate may comprise a flexible portion. The flexible portion may be configured so that the emitter is moveable relative to the sensor by bending the flexible portion. The angle between the emitter and the sensor may preferably be between 20 and 120 degrees, preferably between 60 and 100 degrees, even more preferably 70 and 90 degrees. Most preferably, the angle between the sensor and the emitter may be about 80 degrees. A substrate comprising a flexible portion may advantageously allow the angle between the emitter and the sensor to be controlled in a simple way during the manufacturing process. Using a substrate comprising a flexible portion may advantageously remove the need for the substrate to be pre-moulded to a desired shape. It may be possible to modify the angle between the emitter and sensor during or after the manufacture of the aerosol-forming device. Where the angle between the emitter and the sensor is referred to herein, the angle is defined between the central optical axis of the emitter and the central optical axis of the sensor. This may be the same as the angle defined between the surface of an aerosol-forming substrate or article at least partially received in the cavity and the emitter and sensor. The angle between the normal to the plane of the first portion and the normal to the plane of the second portion may be substantially the same as the angle between the sensor and the emitter.

The substrate may be bent such that the emitter is adjacent a different portion of the cavity to the sensor and such that the angle between the central optical axes of the emitter and sensor is between 20 degrees and 120 degrees, preferably between 60 and 100 degrees, even more preferably 70 and 90 degrees. Most preferably, the angle between the sensor and the emitter may be about 80 degrees.

The substrate may comprise a third portion between the first and second portion. At least the third portion may be flexible such that the first portion is moveable relative to the second portion. This may allow the angle between the emitter and the sensor to be controlled, as described above.

Preferably, the metal backing layer is not provided on a surface of the second outer layer of the third portion of the substrate.

Preferably, the first portion of the substrate may be rigid. The second portion of the substrate may be rigid. In this way, the flexible third portion acts as a hinge between the rigid first and second portions.

Preferably, the third portion of the substrate may be opaque to wavelengths of electromagnetic radiation emitted by the emitter. This may advantageously ensure that electromagnetic radiation emitted by the emitter is not directly received by the sensor before being reflected or absorbed and emitted by the aerosol-forming substrate received in the cavity.

The substrate may comprise one or more PCBs. The substrate may consist of one or more flexible PCBs. At least the third portion of the substrate may comprise or consist of a flexible PCB.

Preferably, the first and second portions of the substrate may comprise a rigid PCB and the third portion may comprise a flexible PCB.

The shielding plate may comprise a planar first portion and a planar second portion. The planar first and second portions of the shielding plate may be non-co-planar. The first portion of the shielding plate may be co-planar to the first portion of the substrate. The second portion of the shielding plate may be co-planar to the second portion of the substrate.

The sensor may be positioned between the first portion of the shielding plate and the cavity. The emitter may be positioned between the second portion of the shielding plate and the cavity.

A particularly preferable combination may be the substrate comprising a flexible portion, as described above, with the shielding plate as described above when the shielding plate comprises first and second planar portions, the second portion being planar in a plane that is different to the first portion. This is because the shielding plate may advantageously hold the substrate so that the flexible portion is bent at a desired angle.

Preferably, the shielding plate may be attached to a second side of the substrate opposite to the first side. The shielding plate may be rigid.

The first portion of the shielding plate may be attached to the first portion of the substrate. The second portion of the shielding plate may be attached to the second portion of the substrate.

This arrangement may allow for a simple manufacture process. Advantageously, the act of attaching the shielding plate to the substrate may hold the substrate at a desired angle.

The shielding plate may comprise at least one clip. The shielding plate may comprise a first clip at a first end and a second clip at a second end. The first end may be at an opposite end of the shielding plate to the second end. The one or more clips may be configured to connect the clip to the second side of the substrate. The one or more clips may advantageously provide a simple and low cost means of attaching the shielding plate onto the substrate. Attaching the shielding plate on to the substrate in this way may advantageously ensure that the sensing assembly is simple and low cost to manufacture.

The shielding plate may be connected to a ground contact of the aerosol-generating device. The ground contact may be on the substrate. The ground contact may be on the PCB if the substrate comprises a PCB. The at least one clip of the shielding plate may be in contact with the ground contact. Connecting the shielding plate to a ground contact may allow the shielding plate to provide good shielding.

The shielding plate may be integrally formed. This may include the at least one clip. The shielding plate may be a monolithic piece. This may include the at least one clip.

The substrate may comprise an intermediate layer arranged between the first outer layer and the second outer layer. The substrate may comprise an intermediate layer arranged between the first outer layer and the second outer layer and the first and second outer layers of the substrate may be printed circuit boards.

The intermediate layer may comprise a metal or an alloy. The intermediate layer may be a metal layer. The intermediate layer may comprise copper. The intermediate layer may be a copper layer.

The extended end portion of the substrate may comprise a metal layer or an alloy layer. The metal layer or alloy layer may be an intermediate layer arranged between the first outer layer and the second outer layer. The metal layer or alloy layer may comprise copper. The extended end portion of the substrate may comprise a copper layer. The copper layer may be an intermediate layer arranged between the first outer layer and the second outer layer.

The extended end portion of the substrate is located adjacent the first portion or adjacent the second portion. Where the extended end portion is located adjacent the first portion, the first portion is located between the extended end portion and the second portion. Where the extended end portion is located adjacent the second portion, the second portion is located between the extended end portion and the first portion.

Where the extended end portion of the substrate located adjacent the first portion of the substrate, the extended end portion of the substrate may extend beyond the first portion over a distance of at least 10 millimeters, preferably at least 12 millimeters, more preferably at least 14 millimeters, more preferably between 10 millimeters and 21 millimeters, more preferably between 14 millimeters and 17 millimeters.

Where the extended end portion of the substrate located adjacent the second portion of the substrate, the extended end portion of the substrate may extend beyond the second portion over a distance of at least 10 millimeters, preferably at least 12 millimeters, more preferably at least 14 millimeters, more preferably between 10 millimeters and 21 millimeters, more preferably between 14 millimeters and 17 millimeters.

The sensing assembly may comprise both the extended end portion of the substrate and the metal backing layer and the surface of the second outer layer of the substrate may be free of the metal backing layer in the area of the extended end portion.

The metal backing layer may be a steel layer. The metal backing layer may be a stainless steel layer. The steel may be a steel according to Japanese Steel Standard JIS SUS304.

The metal backing layer may have a thickness of between 0.1 millimeter and 0.5 millimeter, preferably between 0.2 millimeter and 0.4 millimeter, more preferably between 0.25 millimeter and 0.35 millimeter, more preferably of about 0.3 millimeter.

The metal backing layer may comprise one or more individual metal plates. The metal backing layer may comprise a first metal plate and a second metal plate. The first metal plate may be provided on a first portion of the second outer layer of the substrate opposing the first portion of the first outer layer of the substrate. The second metal plate may be provided on a second portion of the second outer layer of the substrate opposing the second portion of the first outer layer of the substrate. The first metal plate may be provided on a first portion of the second outer layer of the substrate opposing the emitter. The second metal plate may be provided on a second portion of the second outer layer of the substrate opposing the sensor.

The first metal plate may have a width of between 0.2 millimeter and 0.6 millimeter, preferably between 0.35 millimeter and 0.45 millimeter, more preferably of about 0.4 millimeter. The first metal plate may have a length of between 0.7 millimeter and 1.3 millimeters, preferably between 0.95 millimeter and 1.05 millimeters, more preferably of about 1.0 millimeter. The first metal plate may have a thickness of between 0.1 millimeter and 0.5 millimeter, preferably between 0.2 millimeter and 0.4 millimeter, more preferably between 0.25 millimeter and 0.35 millimeter, more preferably of about 0.3 millimeter.

The first metal plate may have a width of between 0.2 millimeter and 0.6 millimeter, preferably between 0.35 millimeter and 0.45 millimeter, more preferably of about 0.4 millimeter. The first metal plate may have a length of between 0.7 millimeter and 1.3 millimeters, preferably between 0.95 millimeter and 1.05 millimeters, more preferably of about 1.0 millimeter. The second metal plate may have a thickness of between 0.1 millimeter and 0.5 millimeter, preferably between 0.2 millimeter and 0.4 millimeter, more preferably between 0.25 millimeter and 0.35 millimeter, more preferably of about 0.3 millimeter.

The first and second metal plates may have the same shape and size, preferably, each of the first and second metal plates has a width of about 0.4 millimeter, a length of about 1.0 millimeter, and a thickness of about 0.3 millimeter.

The sensing assembly may comprise an aerogel layer or aerogel sheet. The aerogel layer or aerogel sheet may be arranged between at least a portion of the substrate and the cavity. The sensing assembly may comprise an aerogel layer or aerogel sheet. The aerogel layer or aerogel sheet may be arranged between at least a portion of the substrate and a longitudinal center axis of the cavity. The aerogel layer or aerogel sheet may have a thickness of between 0.1 millimeter and 0.3 millimeter, preferably of about 0.2 millimeter. The aerogel layer or aerogel sheet may function as a thermal barrier. The aerogel layer or aerogel sheet may assist in thermally insulating the substrate from the heater assembly. The aerogel layer or aerogel sheet may assist in thermally insulating the substrate from the cavity when at least a portion of the cavity is heated during use of the aerosol-generating device.

The cavity may be defined by a housing of the aerosol-generating device. The housing of the aerosol-generating device defining the cavity may comprise a first portion of the housing defining the cavity. The first portion of the housing defining the cavity may be transparent to at least one wavelength of the electromagnetic radiation emitted by the emitter. The first portion of the housing may preferably be transparent to all of the wavelengths of the electromagnetic radiation emitted by the emitter. The emitter may be configured to emit the electromagnetic radiation into the cavity through the transparent portion.

The first portion of the housing may separate the emitter from the cavity. Therefore, the first portion of the housing may protect the emitter from debris and dirt that may accumulate in the cavity. In particular, the emitter may be protected from residue from the aerosol-forming substrate that may accumulate during use of the aerosol-generating device. The first portion may be also advantageously be easy to clean such that the device can simply be maintained.

An airflow path may be defined through the aerosol-generating device from an air inlet to an air outlet. The airflow path may pass through the cavity. The emitter may be separated from air flowing through the airflow path by the transparent first portion of the housing. The air may carry debris or dirt. Therefore, the first portion may protect the emitter from air passing through the airflow path.

The first portion of the housing may be sized and positioned to correspond to the viewing angle of the emitter. This may advantageously ensure that substantially all of the electromagnetic radiation emitted by the emitter in use passes into the cavity.

The housing of the aerosol-generating device defining the cavity may comprise a second portion of the housing defining the cavity. The second portion of the housing defining the cavity may be transparent to at least one wavelength of electromagnetic radiation received by the sensor. The sensor may be configured to receive the electromagnetic radiation from the cavity through the second transparent portion.

The second portion of the housing may have corresponding features and advantages as described with respect to the first portion, only with respect to the sensor rather than with respect to the emitter.

The provision of the first and second portion of the housing may advantageously increase the lifetime of the sensing assembly. The first and second portions of the housing may prevent the sensing assembly from deteriorating over time, for example due to becoming coated with dirt, debris and substrate residue. In a deteriorated sensing assembly, the amount of electromagnetic radiation entering the cavity from the emitter or received by the sensor from the cavity might be reduced which would reduce the accuracy and sensitivity of the sensing assembly.

The cavity of the aerosol-generating device may have an open end into which the aerosol-generating article is inserted. The open end may be a proximal end. The cavity may have a closed end opposite the open end. The closed end may be the base of the cavity. The closed end may be closed except for the provision of air apertures arranged in the base. The base of the cavity may be flat. The base of the cavity may be circular. The base of the cavity may be arranged upstream of the cavity. The open end may be arranged downstream of the cavity. The cavity may have an elongate extension. The cavity may have a longitudinal central axis. A longitudinal direction may be the direction extending between the open and closed ends along the longitudinal central axis. The longitudinal central axis of the cavity may be parallel to the longitudinal axis of the aerosol-generating device.

At least a portion of the cavity may be configured as a heating chamber. A distal portion of the cavity may be configured as a heating chamber. The cavity may have a cylindrical shape. The cavity may have a hollow cylindrical shape. The cavity may have a shape corresponding to the shape of the aerosol-generating article to be received in the cavity. The cavity may have a circular cross-section. The cavity may have an elliptical or rectangular cross-section. The cavity may have an inner diameter corresponding to the outer diameter of the aerosol-generating article.

An airflow channel may run through the cavity. Ambient air may be drawn into the aerosol-generating device, into the cavity and towards the user through the airflow channel. Downstream of the cavity, a mouthpiece may be arranged or a user may directly draw on the aerosol-generating article. The airflow channel may extend through the mouthpiece.

The aerosol-generating device may be configured such that, during operation of the device, the temperature of the sensing assembly does not exceed 120 degrees Celsius, preferably does not exceed 110 degrees Celsius, more preferably does not exceed 100 degrees Celsius, more preferably does not exceed 95 degrees Celsius, more preferably does not exceed 90 degrees Celsius, more preferably does not exceed 87 degrees Celsius.

The aerosol-generating device may comprise at least one lens configured to focus electromagnetic radiation received from the cavity on to the sensor. The lens may comprise an absorption material configured to substantially block wavelengths of electromagnetic radiation that fall outside a range of wavelengths. The absorption material may be configured to substantially block wavelengths of electromagnetic radiation less than 200 nanometers and greater than 30,000 nanometers. The one or more lenses may advantageously increase the amount of electromagnetic radiation received by the sensor. This may advantageously increase the signal to noise ratio of the sensing assembly and so improve the accuracy of the sensing assembly at detecting the presence and type of aerosol-forming substrate at least partially received in the cavity.

The sensing assembly may comprise amplification electronics connected directly to the sensor.

The aerosol-generating device may comprise a controller. The controller may be configured to receive signals from the sensor. The controller may be configured to determine material properties of the aerosol-forming substrate at least partially received in the cavity, based on a measured intensity of the electromagnetic radiation received at the sensor. The controller may be configured to determine material properties of an aerosol-generating article comprising the aerosol-forming substrate, based on a measured intensity of the electromagnetic radiation received at the sensor.

Preferably, the controller may be configured to perform spectral analysis of the measured intensity of the electromagnetic radiation to determine material properties of the aerosol-forming substrate or an aerosol-generating article comprising the aerosol-forming substrate. Based on the determined material properties, the controller may be configured to determine the type of aerosol-forming substrate at least partially received in the cavity. The controller being configured to determine material properties of the aerosol-forming substrate may advantageously means that the type of aerosol-forming substrate can be determined directly based on inherent material properties of the aerosol-forming substrate. There is no need for the aerosol-forming substrate, or for an aerosol-generating article comprising the aerosol-forming substrate, to comprise a printed barcode, taggant or other indicia of the type of the type of substrate.

The material property determined by the controller may be the wetness or water content of the aerosol-forming substrate.

The controller may comprise a memory. Stored in the memory of the controller may be data relating known measurements of electromagnetic radiation at specific wavelengths to chemical structures of, or types of, aerosol-forming substrates. The controller may be configured to determine the type of aerosol-forming substrate received in the cavity by comparing one or more electromagnetic radiation measurements made by the sensor at one or more wavelengths with the known measurements stored in the memory. The aerosol-generating device may comprise a heating assembly for heating the aerosol-forming substrate. The heating assembly may be controlled by the controller. The controller may be configured to control the heating assembly according to a heating profile selected based on the determined type of aerosol-forming substrate.

The controller may be configured to determine the value related to the water content of an aerosol-forming substrate received in the cavity repeatedly during use of the aerosol-generating device. Preferably, the controller may be configured to modify a heating profile based on changes in the determined water content of the aerosol-forming substrate. The changes in determined water content may be relative to an expected water content for the determined type aerosol-forming substrate. Alternatively or additionally the changes in determined water content may be changes in the determined water content over time. For example, the changes in determined water content may be changes in the determined water content during a puff or between puffs.

The emitter may be configured to emit electromagnetic radiation having a wavelength of between 1100 nanometers and 1500 nanometers. Preferably the emitter may be configured to emit electromagnetic radiation having a wavelength of between 1350 nanometers and 1400 nanometers.

The sensor may be configured to receive electromagnetic radiation having a wavelength of between 1100 nanometers and 1500 nanometers. Preferably the sensor may be configured to receive electromagnetic radiation having a wavelength of between 1350 nanometers and 1400 nanometers.

Water is particularly effective at absorbing electromagnetic radiation having a wavelength between 1100 nanometers and 1500 nanometers, and in particular between 1350 nanometers and 1400 nanometers. Thus, it may be advantageous for the emitter and sensor to emit and receive such wavelengths of electromagnetic radiation when the material property of interest of the aerosol-forming substrate is wetness or water content.

The emitter may comprise at least one LED to emit the electromagnetic radiation.

Preferably, the emitter may be configured to emit a plurality of wavelengths of electromagnetic radiation. The emitter may comprise a plurality of LEDs, each of the plurality of LEDs being configured to emit a different wavelength of electromagnetic radiation.

The sensor may comprise a photodiode.

The sensor may be configured to receive a plurality of wavelengths of electromagnetic radiation. In particular, the sensor may be configured to measure a plurality of wavelengths of the received electromagnetic radiation.

In other words, the sensing assembly may be configured to perform spectroscopy on an aerosol-forming substrate received in the cavity, or on an aerosol-generating article comprising the substrate received in the cavity. The device may comprise a controller to perform spectral analysis on the measured electromagnetic radiation. Based on the spectral analysis, the controller may be configured to determine the presence of an aerosol-forming substrate in the cavity. The controller may be configured to determine the type of aerosol-forming substrate in the cavity.

Herein, determining the presence and type of an aerosol-forming substrate is used interchangeably with determining the presence and type of an aerosol-generating article comprising an aerosol-forming substrate. In either case, the aerosol-generating device may advantageously be configured to determine the presence and type of the aerosol-forming substrate or article based on its chemical composition.

In one example, the electromagnetic radiation emitted by the emitter may be incident on an aerosol-forming substrate, in which case the presence or type of aerosol-forming substrate may be determined.

Alternatively, the aerosol-forming substrate may be contained in an aerosol-generating article. In that case, the electromagnetic radiation received by the sensor may be affected by the chemical structure of the aerosol-generating article, for example a wrapper or housing of the article. Different aerosol-generating articles may comprise different chemical structures, for example different wrappers or housings. This may allow for different aerosol-generating articles to be identified.

“Different aerosol-generating article” may refer to aerosol-generating articles comprising different aerosol-forming substrates.

Furthermore, a portion of the electromagnetic radiation may pass through the aerosol-generating device to the aerosol-forming substrate such that electromagnetic radiation received by the sensor may have been affected by the chemical structure of both the aerosol-generating article and substrate.

The aerosol-forming substrate may be a solid aerosol-forming substrate. Alternatively, the aerosol-forming substrate may comprise both solid and liquid components. The aerosol-forming substrate may comprise a tobacco-containing material containing volatile tobacco flavour compounds which are released from the substrate upon heating. Alternatively, the aerosol-forming substrate may comprise a non-tobacco material. The aerosol-forming substrate may further comprise an aerosol former that facilitates the formation of a dense and stable aerosol. Examples of suitable aerosol formers are glycerine and propylene glycol.

If the aerosol-forming substrate is a solid aerosol-forming substrate, the solid aerosol-forming substrate may comprise, for example, one or more of: powder, granules, pellets, shreds, spaghettis, strips or sheets containing one or more of: herb leaf, tobacco leaf, fragments of tobacco ribs, reconstituted tobacco, homogenised tobacco, extruded tobacco, cast leaf tobacco and expanded tobacco. The solid aerosol-forming substrate may be in loose form, or may be provided in a suitable container or cartridge. Optionally, the solid aerosol-forming substrate may contain additional tobacco or non-tobacco volatile flavour compounds, to be released upon heating of the substrate. The solid aerosol-forming substrate may also contain capsules that, for example, include the additional tobacco or non-tobacco volatile flavour compounds and such capsules may melt during heating of the solid aerosol-forming substrate.

As used herein, homogenised tobacco refers to material formed by agglomerating particulate tobacco. Homogenised tobacco may be in the form of a sheet. Homogenised tobacco material may have an aerosol-former content of greater than 5% on a dry weight basis. Homogenised tobacco material may alternatively have an aerosol former content of between 5% and 30% by weight on a dry weight basis. Sheets of homogenised tobacco material may be formed by agglomerating particulate tobacco obtained by grinding or otherwise combining one or both of tobacco leaf lamina and tobacco leaf stems. Alternatively, or in addition, sheets of homogenised tobacco material may comprise one or more of tobacco dust, tobacco fines and other particulate tobacco by-products formed during, for example, the treating, handling and shipping of tobacco. Sheets of homogenised tobacco material may comprise one or more intrinsic binders, that is tobacco endogenous binders, one or more extrinsic binders, that is tobacco exogenous binders, or a combination thereof to help agglomerate the particulate tobacco; alternatively, or in addition, sheets of homogenised tobacco material may comprise other additives including, but not limited to, tobacco and non-tobacco fibres, aerosol-formers, humectants, plasticisers, flavourants, fillers, aqueous and non-aqueous solvents and combinations thereof.

Optionally, the solid aerosol-forming substrate may be provided on or embedded in a thermally stable carrier. The carrier may take the form of powder, granules, pellets, shreds, spaghettis, strips or sheets. Alternatively, the carrier may be a tubular carrier having a thin layer of the solid substrate deposited on its inner surface, or on its outer surface, or on both its inner and outer surfaces. Such a tubular carrier may be formed of, for example, a paper, or paper like material, a non-woven carbon fibre mat, a low mass open mesh metallic screen, or a perforated metallic foil or any other thermally stable polymer matrix.

In a particularly preferred embodiment, the aerosol-forming substrate comprises a gathered crimpled sheet of homogenised tobacco material. As used herein, the term ‘crimped sheet’ denotes a sheet having a plurality of substantially parallel ridges or corrugations. Preferably, when the aerosol-generating article has been assembled, the substantially parallel ridges or corrugations extend along or parallel to the longitudinal axis of the aerosol-generating article. This advantageously facilitates gathering of the crimped sheet of homogenised tobacco material to form the aerosol-forming substrate. However, it will be appreciated that crimped sheets of homogenised tobacco material for inclusion in the aerosol-generating article may alternatively or in addition have a plurality of substantially parallel ridges or corrugations that are disposed at an acute or obtuse angle to the longitudinal axis of the aerosol-generating article when the aerosol-generating article has been assembled. In certain embodiments, the aerosol-forming substrate may comprise a gathered sheet of homogenised tobacco material that is substantially evenly textured over substantially its entire surface. For example, the aerosol-forming substrate may comprise a gathered crimped sheet of homogenised tobacco material comprising a plurality of substantially parallel ridges or corrugations that are substantially evenly spaced-apart across the width of the sheet.

The solid aerosol-forming substrate may be deposited on the surface of the carrier in the form of, for example, a sheet, foam, gel or slurry. The solid aerosol-forming substrate may be deposited on the entire surface of the carrier, or alternatively, may be deposited in a pattern in order to provide a non-uniform flavour delivery during use.

The aerosol-generating device may comprise a heater assembly. The heater assembly may be configured to heat an aerosol-forming substrate received in the cavity in use. The controller may be configured to control the heater assembly. The control of the heater assembly may be based on the type of aerosol-forming substrate determined by the controller. Preferably, the controller may be configured to control the heater assembly according to a heating profile. The heating profile may be chosen or modified according to the type of aerosol-forming substrate at least partially received in the cavity.

The heater assembly may comprise a heating element. In use, power may be supplied to the heating element, causing the heating element to heat up. The heat may then be transferred to a received aerosol-forming substrate, for example by conduction through the device housing forming the chamber.

The heating element may be a resistive heating element. The heating element may comprise an electrically resistive material. Suitable electrically resistive materials include but are not limited to: semiconductors such as doped ceramics, electrically “conductive” ceramics (such as, for example, molybdenum disilicide), carbon, graphite, metals, metal allows and composition materials made of ceramic material and a metallic material. Such composite materials may comprise doped and undoped ceramics.

In another example, the heater assembly may comprise one or more inductor coils and the heating element may comprise one or more susceptor elements.

The one or more susceptor elements may be configured to be heatable by an alternating magnetic field generated by the inductor coil or coils. In use, electrical power supplied to an inductor coil (for example, by a power source of the device) may result in the inductor coil inducing eddy currents in a susceptor element. These eddy currents, in turn, result in the susceptor element generating heat. The electrical power is supplied to the inductor coil as an alternating magnetic field. The alternating current may have any suitable frequency. The alternating current may preferably be a high frequency alternating current. The alternating current may have a frequency between 100 kilohertz (kHz) and 30 megahertz (MHz). When an aerosol-forming substrate is received in the chamber, the heat generated by the susceptor element may heat the aerosol-forming substrate to a temperature sufficient to cause aerosol to evolve from the substrate. The susceptor element may be formed of a material having an ability to absorb electromagnetic energy and convert it into heat. By way of example and without limitation, the susceptor element may be formed of a ferromagnetic material, such as a steel.

The aerosol-generating device may comprise a power supply which may be configured to supply current to the resistive heating element.

The heating element may comprise a substrate layer of flexible material. The substrate layer may comprise a thermally stable polymer, preferably polyimide.

The heating element may be arranged on the substrate layer. The heating element may contain wire connections configured for being connected with a controller of the aerosol-generating device. The heating element may comprise heating tracks arranged on the substrate layer. The heating tracks may comprise a thermally conductive material, preferably a metal such as stainless steel. The heating tracks may be electrically connected to said wire connections.

The heating element may take other forms. For example, a metallic grid or grids, a flexible printed circuit board, a molded interconnect device (MID), ceramic heater, flexible carbon fibre heater or may be formed using a coating technique such as plasma vapour deposition, on a suitably shaped substrate.

As used herein, transparency to certain wavelengths of electromagnetic radiation, in the context of the transparent portion or otherwise, means that at least 90%, preferably at least 95%, even more preferably at least 99% of the electromagnetic radiation at that wavelength can pass through the first or second portion without being absorbed.

The invention further relates to a sensing assembly for an aerosol-generating device for generating aerosol from an aerosol-forming substrate. The aerosol-generating device may comprise a cavity for receiving an aerosol-forming substrate. The sensing assembly may comprise a multilayer substrate. The multilayer substrate may comprise a first outer layer defining a first side of the substrate. The multilayer substrate may comprise a second outer layer defining a second side of the substrate. The sensing assembly may comprise an emitter configured to emit electromagnetic radiation into the cavity. The emitter may be provided on the first outer layer on a first portion of the substrate. The sensing assembly may comprise a sensor configured to measure at least one wavelength of a received electromagnetic radiation. The sensor may be provided on the first outer layer on a second portion of the substrate. The sensing assembly may comprise at least one heat dissipating structure. The heat dissipating structure may be selected from a metal backing layer provided on a surface of the second outer layer of the substrate, and an extended end portion of the substrate located adjacent the first portion or adjacent the second portion. The extended end portion may extend at least 5 millimeters beyond said first or second portion. The extended end portion may be free of any electrically conductive tracks on a surface thereof.

The sensing assembly may comprise any of the features described in relation to any one of the previous aspects of the disclosure.

The invention further relates to an aerosol-generating system comprising the aerosol-generating device as described herein and an aerosol-generating article comprising the aerosol-forming substrate.

As used herein, the terms ‘proximal’, ‘distal’, ‘downstream’ and ‘upstream’ are used to describe the relative positions of components, or portions of components, of the aerosol-generating device in relation to the direction in which a user draws on the aerosol-generating device during use thereof.

As used herein, an ‘aerosol-generating device’ relates to a device that interacts with an aerosol-forming substrate to generate an aerosol. The aerosol-forming substrate may be part of an aerosol-generating article, for example part of a smoking article. An aerosol-generating device may be a smoking device that interacts with an aerosol-forming substrate of an aerosol-generating article to generate an aerosol that is directly inhalable into a user's lungs thorough the user's mouth. An aerosol-generating device may be a holder. The device may be an electrically heated smoking device. The aerosol-generating device may comprise a housing, electric circuitry, a power supply, a heating chamber and a heating element.

As used herein, the term ‘aerosol-generating article’ refers to an article comprising an aerosol-forming substrate that is capable of releasing volatile compounds that can form an aerosol. For example, an aerosol-generating article may be a smoking article that generates an aerosol that is directly inhalable into a user's lungs through the user's mouth. An aerosol-generating article may be disposable.

As used herein, the term ‘aerosol-forming substrate’ relates to a substrate capable of releasing one or more volatile compounds that can form an aerosol. Such volatile compounds may be released by heating the aerosol-forming substrate. An aerosol-forming substrate may conveniently be part of an aerosol-generating article or smoking article.

Below, there is provided a non-exhaustive list of non-limiting examples. Any one or more of the features of these examples may be combined with any one or more features of another example, embodiment, or aspect described herein.

Example E1: An aerosol-generating device comprising a cavity for receiving an aerosol-forming substrate and a sensing assembly for detecting the aerosol-forming substrate in the cavity; the sensing assembly comprising
a multilayer substrate comprising a first outer layer defining a first side of the substrate and a second outer layer defining a second side of the substrate;
an emitter configured to emit electromagnetic radiation into the cavity and being provided on the first outer layer on a first portion of the substrate;
a sensor configured to measure at least one wavelength of a received electromagnetic radiation and being provided on the first outer layer on a second portion of the substrate; and
at least one heat dissipating structure selected from:
a metal backing layer provided on a surface of the second outer layer of the substrate, and
an extended end portion of the substrate located adjacent the first portion or adjacent the second portion, the extended end portion extending at least 5 millimeters beyond said first or second portion and being free of any electrically conductive tracks on a surface thereof.

Example E2: The aerosol-generating device according to Example E1, wherein the substrate comprises one or more printed circuit boards, preferably one or more flexible printed circuit boards.

Example E3: The aerosol-generating device according to Example E1 or Example E2, wherein the substrate comprises an intermediate layer arranged between the first outer layer and the second outer layer, preferably wherein the first and second outer layers of the substrate are printed circuit boards.

Example E4: The aerosol-generating device according to Example E3, wherein the intermediate layer is a metal layer, preferably wherein the intermediate layer comprises copper, more preferably wherein the intermediate layer is a copper layer.

Example E5: The aerosol-generating device according to any of the preceding examples comprising the extended end portion of the substrate, wherein the extended end portion comprises a copper layer, preferably wherein the copper layer is an intermediate layer arranged between the first outer layer and the second outer layer.

Example E6: The aerosol-generating device according to any of the preceding examples comprising the extended end portion of the substrate located adjacent the first portion or adjacent the second portion, wherein the extended end portion extends beyond said first or second portion over a distance of at least 10 millimeters, preferably at least 12 millimeters, more preferably at least 14 millimeters, more preferably between 14 millimeters and 17 millimeters.

Example E7: The aerosol-generating device according to any of the preceding examples, comprising both the extended end portion of the substrate and the metal backing layer, and wherein the metal backing layer is not provided on a surface of the second outer layer of the substrate in the area of the extended end portion.

Example E8: The aerosol-generating device according to any of the preceding examples comprising the metal backing layer, wherein the metal backing layer is a steel layer, preferably a stainless steel layer, more preferably wherein the steel is JIS SUS304.

Example E9: The aerosol-generating device according to any of the preceding examples comprising the metal backing layer, wherein the metal backing layer has a thickness of between 0.1 millimeter and 0.5 millimeter, preferably between 0.2 millimeter and 0.4 millimeter, more preferably between 0.25 millimeter and 0.35 millimeter.

Example E10: The aerosol-generating device according to any of the preceding examples comprising the metal backing layer, wherein the metal backing layer comprises first and second individual metal plates, preferably wherein the first metal plate is provided on a first portion of the second outer layer of the substrate opposing the first portion of the first outer layer of the substrate and the second metal plate is provided on a second portion of the second outer layer of the substrate opposing the second portion of the first outer layer of the substrate.

Example E11: The aerosol-generating device according to Example E10, wherein each of the first and second metal plates has a width of between 0.2 millimeter and 0.6 millimeter, preferably between 0.35 millimeter and 0.45 millimeter, and a length of between 0.7 millimeter and 1.3 millimeters, preferably between 0.95 millimeter and 1.05 millimeters.

Example E12: The aerosol-generating device according to any of the preceding examples, wherein the first and second portions of the substrate are planar and are non-co-planar, preferably wherein an angle between a normal to the planar first portion and a normal to the planar second portion of the substrate is between 60 degrees and 100 degrees, preferably between 70 and 90 degrees, more preferably is about 80 degrees.

Example E13: The aerosol-generating device according to any of the preceding examples comprising an aerogel layer arranged between the substrate and a longitudinal center axis of the cavity, preferably wherein the aerogel layer has a thickness of between 0.1 millimeter and 0.3 millimeter.

Example E14: The aerosol-generating device according to any of the preceding examples, wherein at least a portion of the substrate is flexible.

Example E15: The aerosol-generating device according to Example E14, wherein the substrate further comprises a third portion between the first and second portion, and wherein at least the third portion is flexible such that the first portion is moveable relative to the second portion, preferably wherein the metal backing layer is not provided on a surface of the second outer layer of the third portion of the substrate.

Example E16: The aerosol-generating device according to Example E15, wherein the flexible portion is configured so that the emitter is moveable relative to the sensor by bending the flexible portion.

Example E17: The aerosol-generating device according to Example E16, wherein the substrate is bent such that an angle between a central optical axis of the emitter and a central optical axis of the sensor is between 20 degrees and 120 degrees, preferably between 60 and 100 degrees, more preferably between 70 and 90 degrees, more preferably is about 80 degrees.

Example E18: The aerosol-generating device according to any of the preceding examples, comprising a shielding plate configured to block electromagnetic radiation and being positioned externally to the cavity such that the sensor is arranged between a longitudinal center axis of the cavity and at least a portion of the shielding plate, preferably wherein the sensor is positioned between a first portion of the shielding plate and the cavity and the emitter is positioned between a second portion of the shielding plate and the cavity.

Example E19: The aerosol-generating device according to any of the preceding examples, wherein the temperature of the sensing assembly does not exceed 120 degrees Celsius, preferably does not exceed 110 degrees Celsius, more preferably does not exceed 100 degrees Celsius, more preferably does not exceed 95 degrees Celsius, more preferably does not exceed 90 degrees Celsius, more preferably does not exceed 87 degrees Celsius during operation of the device.

Example E20: The aerosol-generating device according to any of the preceding examples, wherein the cavity is defined by a housing of the device, and wherein a first portion of the housing is transparent to at least some of the wavelengths of the electromagnetic radiation emitted by the emitter, and wherein the emitter is configured to emit the electromagnetic radiation into the cavity through the transparent portion.

Example E21: The aerosol-generating device according to any of the preceding examples, wherein the sensing assembly further comprises amplification electronics connected directly to the sensor.

Example E22: The aerosol-generating device according to any of the preceding examples, further comprising a controller configured to receive signals from the sensor, wherein the controller is configured to determine material properties of the aerosol-forming substrate at least partially received in the cavity, or an aerosol-generating article comprising the aerosol-forming substrate, based on a measured intensity of the electromagnetic radiation received at the sensor.

Example E23: The aerosol-generating device according to Example E22, wherein the material properties determined by the controller comprise the wetness or water content of the aerosol-forming substrate.

Example E24: An aerosol-generating system comprising the aerosol-generating device according to any of the preceding examples and an aerosol-generating article comprising the aerosol-forming substrate.

Features described in relation to one embodiment may equally be applied to other embodiments of the invention.

The invention will be further described, by way of example only, with reference to the accompanying drawings in which:

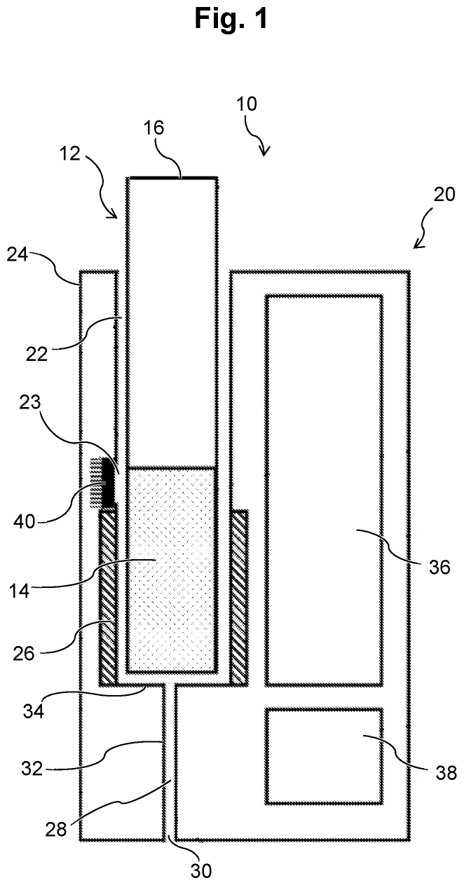

FIG. 1 shows an aerosol-generating system;

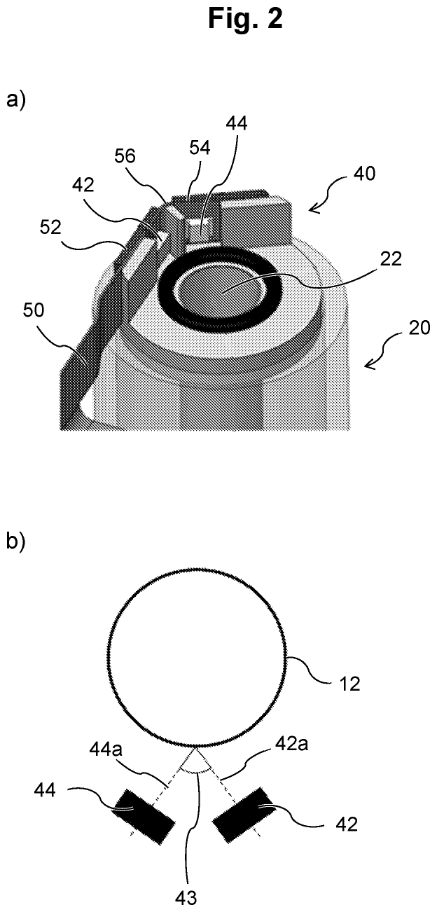

FIGS. 2a and 2b show a sensing assembly;

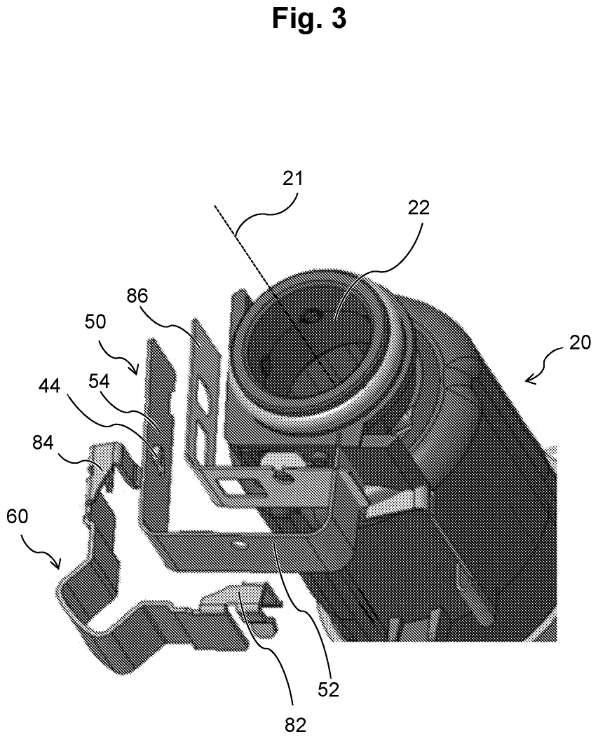

FIG. 3 shows a sensing assembly;

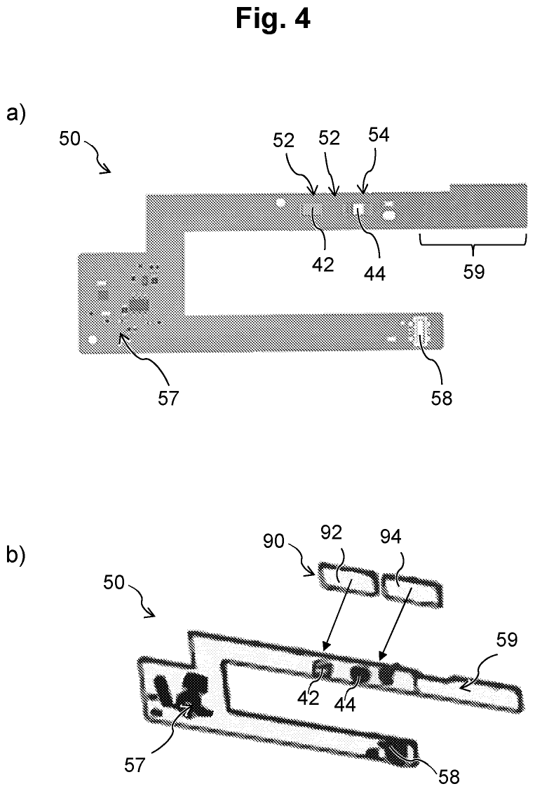

FIGS. 4a and 4b show a multilayer substrate; and

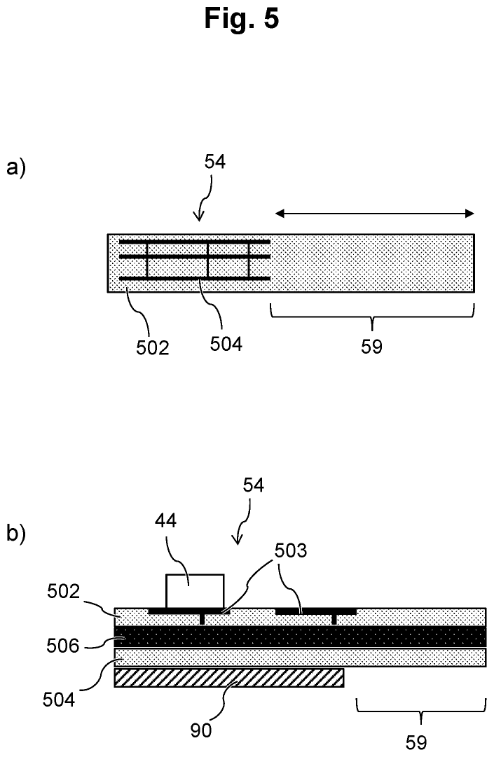

FIGS. 5a and 5b show a multilayer substrate.

FIG. 1 shows an aerosol-generating system 10 in cross-sectional view. The aerosol-generating system 10 comprises an aerosol-generating article 12. The aerosol-generating article 12 comprises an aerosol-forming substrate 14 at a distal part thereof. The aerosol-generating system 10 further comprises an aerosol-generating device 20. The aerosol-generating device 20 comprises a cavity 22 for receiving the aerosol-forming substrate 14. The cavity 22 is defined by a housing 24 of the aerosol-generating device 20.

In the configuration shown in FIG. 1, a distal part of the aerosol-generating article 12 comprising the aerosol-forming substrate 14 has been inserted into the cavity 22. The aerosol-forming substrate 14 may be a solid tobacco-containing substrate. In particular, the aerosol-forming substrate 14 may be a gathered sheet of homogenised tobacco.

As shown in FIG. 1, the aerosol-generating article 12 and cavity 22 are configured such that a mouth end of the aerosol-generating article 12 protrudes out of the cavity 22 and out of the aerosol-generating device 16 when the aerosol-generating article 12 is received in the cavity 22. This mouth end forms a mouthpiece 16 on which a user of the aerosol-generating device may puff in use.

The aerosol-generating device 20 comprises a heater assembly comprising a heating element 26. The heating element 26 surrounds the cavity 22 along a portion of the cavity 22 in which the aerosol-forming substrate 14 of the aerosol-generating article 12 is received. In an alternative embodiment, the heating element 26 may form a portion of the housing 24 that defines the part of the cavity 22 that receives the aerosol-forming substrate 14. The heating element 26 may be a resistive heating element.

An airflow channel 28 extends from an air inlet 30 of the aerosol-generating device 20. Upstream of the cavity 22, the airflow channel 28 is primarily defined by an airflow channel wall 32. Downstream of the airflow channel wall 32, the airflow channel 28 passes through an air inlet defined in the base 34 of the cavity 22. The airflow channel 28 then extends through the cavity 22. When an aerosol-generating article 12 is received in the cavity 22, the airflow channel 28 passes through the aerosol-generating article 12 and extends through the mouthpiece 16.

The aerosol-generating device 20 further comprises a power supply 36 in form of a rechargeable battery for powering the heating element 26 controllable by a controller 38. The power supply 36 is connected to the controller 38 and the heating element 26 via electrical wires and connections that are not shown in the Figures. The aerosol-generating device 20 may comprise further elements, not shown in the Figures, such as a button for activating the aerosol-generating device 20.

The aerosol-generating device 20 further comprises a sensing assembly 40 for detecting the aerosol-forming substrate 14 in the cavity 22.

FIG. 2a more clearly shows the sensing assembly 40. FIG. 2a is a perspective view of the sensing assembly 40 with a cut away portion of the aerosol-generating device 20.

The sensing assembly 40 comprises an emitter 42. The emitter 42 comprises a plurality of LEDs. Each of the LEDs is configured to emit a different wavelength of electromagnetic radiation. The emitter 42, and in particular the plurality of LEDs of the emitter 42, is configured to emit the electromagnetic radiation into the cavity 22. The emitter 42 is configured to emit electromagnetic radiation having wavelengths of between 1350 and 1400 nanometers.

As shown in FIG. 1, the housing 24 that defines the part of the cavity 22 comprises a first transparent portion 23. The emitter 42 is separated from the cavity 22 by the first transparent portion 23 and is configured to emit electromagnetic radiation into the cavity 22 through the first transparent portion 23. The provision of the first transparent portion 23 protects the emitter 42 from debris and dirt that can accumulate in the cavity 22 after prolonged use of the device 20 and can be easily cleaned.

As shown in FIG. 2a, the sensing assembly 40 further comprises a sensor 44. The sensor 44 is configured to receive electromagnetic radiation from the cavity 22. In particular, the sensor 44 is configured to receive electromagnetic radiation from the cavity 22 that was emitted by the emitter 42 and then reflected or transmitted by the aerosol-generating article 12 towards the sensor 44. The sensor 44 comprises a photodiode. The sensor 44 is configured to measure a plurality of wavelengths of the received electromagnetic radiation. In particular, the sensor 44 is configured to measure the intensity of the plurality of wavelengths of received electromagnetic radiation. The sensor 44 is configured to receive electromagnetic radiation having wavelengths of between 1350 and 1400 nanometers.

The cavity 22 comprises a second transparent portion, not shown in the Figures. The sensor 44 is separated from the cavity 22 by the second transparent portion and is configured to receive electromagnetic radiation from the cavity 22 through the second transparent portion.

The sensing assembly 40 further comprises a multilayer substrate 50 comprising a first outer layer defining a first side of the substrate 50 and a second outer layer defining a second side of the substrate 50. The emitter 42 is provided on the first outer layer on a first portion 52 of the substrate 50. The sensor 44 is provided on the first outer layer on a second portion 54 of the substrate 50.

Both the first and second portions 52, 54 of the substrate 50 are planar. The substrate 50 further comprises a third portion 56 which is flexible. As is shown most clearly in FIGS. 2a and 3, the third portion 56 has been bent such that the angle between the first portion 52 and the second portion 54 is 100 degrees. Thus, the angle between the normal to the first portion 52 and the normal to the second portion 54 is 80 degrees. This also means that the angle between the central optical axis of the emitter 42 and the central optical axis of the sensor 44 is 80 degrees (see FIG. 2b). This provides the optimum optical performance.

The third portion 56 is opaque to wavelengths of electromagnetic radiation emitted by the emitter 42. This ensures that electromagnetic radiation emitted by the emitter 42 is not directly received by the sensor 44. The substrate 50 comprises further flexible portions which allow the substrate 50 to be folded into the shape shown in FIGS. 2a and 3.

FIG. 2b shows the angle between the aerosol-generating article 12, the emitter 42 and the sensor 44. FIG. 2b. is a cross-section of the aerosol-generating article 12 and the emitter 42 and sensor 44 separately from the rest of the device 20. The optimum angle between a central optical axis 42a of the emitter 42 and a central optical axis 44a of the sensor 44 is 80 degrees. The angle is represented by numeral 43 in FIG. 2b.

FIG. 3 shows another cut away perspective view of a section of the aerosol-generating device 20 including the sensing assembly 40 (but looking towards the cavity from approximately the opposite direction in comparison to FIG. 2a). FIG. 3 shows several parts of the sensing assembly 40 in an exploded-view, namely a shielding plate 60, the substrate 50, and an aerogel layer 86.

In an assembled configuration, these components are attached on top of one another. The aerogel layer 86 is arranged between the substrate 50 and a longitudinal center axis 21 of the cavity 22. The aerogel layer 86 has a thickness of about 0.2 millimeter.

The shielding plate 60 is configured to block electromagnetic radiation and is positioned externally to the cavity such that the sensor 44 is arranged between the cavity 22 and at least a portion of the shielding plate 60. In the embodiment shown, both the sensor 44 and the emitter 42 are positioned between the shielding plate 60 and the cavity 22. In this way, electromagnetic radiation that is external to the cavity 22 and sensing assembly 40 is blocked from reaching the emitter 42 and, more importantly, the sensor 44. This means that the amount of external electromagnetic radiation received at the sensor 44 is substantially reduced or eliminated and so is not detected as noise at the sensor 44.

The shielding plate 60 is rigid enough that it is able to maintain and hold the first portion 52 of the substrate 50 relative to the second portion 54 such that the angle between the normal to the first portion 52 and the normal to the second portion 54 is 80 degrees.

The shielding plate 60 comprises a first clip 82 at a first end and a second clip 84 at a second end, the first end being at an opposite end of the shielding plate 60 to the second end. The first and second clips 82, 84 are configured to connect the shielding plate 60 to the substrate 50.

As can be seen in FIG. 1, the sensing assembly 40 is positioned relatively close to the heating element 26. Thus, during use of the aerosol-generating device 20 when current is passing through the heating element 26 such that it heats up, heat will inevitably be transferred from the heating element 26 to the sensing assembly 40. The emitter 42 and sensor 44 can be damaged when they are overheated. Heat dissipating structures of the sensing assembly 40 dissipating heat away from the emitter 42 and sensor 44 may reduce the risk of the emitter 42 and sensor 44 being damaged. This will now be explained in more detail.

FIG. 4a shows the substrate 50 separately from the rest of the aerosol-generating device 20 and laid out flat in top view. The substrate 50 of the sensing assembly 40 further comprises analogue amplification electronics 57 which are configured to amplify signals generated by the sensor 44. The amplification electronics 57 are attached to a fourth portion of the substrate 50. By providing the amplification electronics 57 on the same printed circuit board (PCB) of the substrate 50 as the sensor 44, there can be a direct electrical connection between the amplification electronics 57 and the sensor 44. This minimizes the number of electrical connections between the amplification electronics 57 and the sensor 44 and so minimizes the amount of noise introduced to signals generated by the sensor 44 before those signals have been amplified.

The substrate 50 further comprises a connector 58. The connector 58 is used to connect the substrate 50 to the electronics of the rest of aerosol-generating device 20, in particular the controller 38 and the power supply 36.

The substrate 50 further comprises an extended end portion 59 of the substrate 50 located adjacent the second portion 54. The extended end portion 59 extends about 16 millimeters beyond said second portion 54 and is free of any electrically conductive tracks on a surface thereof. The extended end portion 59 functions as a heat dissipating structure to dissipate heat away from the sensor 44, during use.

The flexible third portion 56 of the substrate 50 has already been described. The substrate 50 comprises further flexible portions which allow the substrate 50 to be folded into the shape shown in FIG. 2a and FIG. 3.

FIG. 4b shows an embodiment of the substrate 50 separately from the rest of the aerosol-generating device 20 and laid out flat in perspective view. The substrate 50 of FIG. 4b differs from the substrate 50 of FIG. 4a in that the substrate 50 of FIG. 4b additionally comprises a metal backing layer 90 provided on a back surface, i.e. on the second outer layer, of the substrate 50 as indicated by arrows in FIG. 4b. The metal backing layer 90 comprises a first metal plate 92 and a second metal plate 94. The first and second metal plates 92, 94 are made of stainless steel, preferably a JIS SUS304 steel. Each of the first and second metal plates 92, 94 has a width of about 0.4 millimeter and a length of about 1.0 millimeter. The first metal plate 92 is provided at the backside of the first portion 52 of the substrate 50 opposing the emitter 42. The second metal plate 94 is provided at the backside of the second portion 54 of the substrate 50 opposing the sensor 44.

The metal backing layer 90 functions as a heat dissipating structure to dissipate heat away from the emitter 42 and the sensor 44 during use. In addition, the metal backing layer 90 functions as a stiffener to provide mechanical stability to the first and second portions 52 of the substrate 50.

FIG. 5a shows in top view a subsection of a substrate 50 comprising a part of the second portion 54 and the extended end portion 59. The second portion 54 comprises electrically conductive tracks 503 on a surface thereof. The extended end portion 59 is free of any electrically conductive tracks on a surface thereof. The extended end portion 59 extends by a distance of at least 5 millimeters beyond the second portion 54, the distance being indicated by a double-ended arrow in FIG. 5a.

FIG. 5b shows in cross-sectional view a subsection of a substrate 50 comprising a part of the second portion 54 and the extended end portion 59 and a metal backing layer 90. The metal backing layer 90 has a thickness of about 0.3 millimeter.

FIG. 5b shows that the multilayer substrate 50 comprises a first outer layer 502 defining a first side of the substrate 50. The first outer layer 502 is a PCB comprising electrically conductive tracks 503 in the area of the second portion 54 but not in the area of the extended end portion 59. The sensor 44 is attached to the first outer layer 502 in the area of the second portion 54 and is electrically connected via the electrically conductive tracks 503. The multilayer substrate 50 comprises a second outer layer 504 defining a second side of the substrate 50. The second outer layer 504 of the substrate 50 is a PCB.

The substrate 50 further comprises an intermediate layer 506 arranged between the first outer layer 502 and the second outer layer 504. The intermediate layer 506 is a copper layer.

The extended end portion 59 of the substrate 50 also comprises the copper intermediate layer 506 arranged between the first outer layer 502 and the second outer layer 504. The metal backing layer 90, however, is not provided on a surface of the second outer layer 504 of the substrate 50 in the area of the extended end portion 59.

In use of the aerosol-generating device 20, an aerosol-generating article 12 is received in the cavity 22, as shown in FIG. 1. The sensing assembly 40, in conjunction with the controller 38, is capable of detecting the presence of the aerosol-generating article 12. The emitter 42 of the sensing assembly 40 emits electromagnetic radiation at a plurality of wavelengths. This radiation is then reflected and/or transmitted by the aerosol-generating article 12. Because the viewing angles of the emitter 42 and sensor 44 substantially overlap when the angle between the central optical axis of the emitter 42 and the central optical axis of the sensor 44 is 80 degrees, a significant amount of the reflected and/or transmitted electromagnetic radiation is received by the sensor 44. The sensor 44 measures the intensity of the various wavelengths of received electromagnetic radiation. In doing so, the sensor 44 generates electrical signals. These electrical signals pass directly to amplification electronics to be amplified before being received at the controller 38. The controller 38 is configured to perform spectral analysis on the measurements of intensity of the electromagnetic radiation at different wavelengths. This comprises comparing the intensities of the different wavelengths of electromagnetic radiation with the known distribution of intensities emitted by the emitter 42. Based on the spectral analysis, the controller 38 is configured to determine the presence of the aerosol-generating article 12.

The controller 38 is also configured to determine the type of aerosol-generating article 12 based on the spectral analysis. Different types of aerosol-generating articles 12 can be received in the cavity 22. In particular, aerosol-generating articles 12 having aerosol-forming substrate 14 of differing chemistry can be received in the cavity 22. Because the aerosol-generating articles 12 and aerosol-forming substrates have differing chemistry and/or other material properties, the different aerosol-generating articles 12 will reflect or transmit the plurality of wavelengths of electromagnetic radiation emitted by the emitter 42 to different extents. This will mean that the spectrum of electromagnetic radiation received by the sensor 44 will be different for different aerosol-generating articles 12. The spectrum for a particular type of aerosol-generating article 12 is predictable. So, based on spectral analysis, the controller 38 can determine the type of aerosol-generating article 12 received in the cavity 22.

The controller 38 is configured to control the heating element 26 according to an appropriate heating profile for the determined type of aerosol-generating article 12.

Based on this spectral analysis the controller 38 is also configured to determine material properties of the aerosol-generating article 12 received in the cavity 22. In particular, the controller 38 is configured to determine material properties of the aerosol-forming substrate 14 of the aerosol-generating article 12. The material property determined by the controller 38 is the wetness or water content of the aerosol-forming substrate.

The controller 38 is configured to determine a value related to the water content of an aerosol-forming substrate 14 received in the cavity 22 based on the measured intensity of the electromagnetic radiation received at the sensor 44. As explained above, the emitter 42 and sensor 44 are configured, respectively, to emit and receive wavelengths of electromagnetic radiation having wavelengths between 1350 nanometers and 1400 nanometers. Water is particularly effective at absorbing this range of electromagnetic radiation. Therefore, the intensity of radiation received by the sensor 44 is highly dependent on the water content of aerosol-forming substrate 14 and the controller 38 is able to determine a value associated with water content of the aerosol-forming substrate 14 based on spectral analysis of electromagnetic radiation received by the sensor 44

1.-24. (canceled)

25. An aerosol-generating device comprising a cavity configured to receive an aerosol-forming substrate and a sensing assembly configured to detect the aerosol-forming substrate in the cavity; the sensing assembly comprising:
a multilayer substrate comprising a first outer layer defining a first side of the aerosol-forming substrate and a second outer layer defining a second side of the aerosol-forming substrate;
an emitter configured to emit electromagnetic radiation into the cavity and being provided on the first outer layer on a first portion of the aerosol-forming substrate;
a sensor configured to measure at least one wavelength of a received electromagnetic radiation and being provided on the first outer layer on a second portion of the aerosol-forming substrate; and
at least one heat dissipating structure selected from:
a metal backing layer provided on a surface of the second outer layer of the multilayer substrate, and
an extended end portion of the aerosol-forming substrate located adjacent the first portion or adjacent the second portion, the extended end portion extending at least 5 millimeters beyond the first or the second portion and being free of any electrically conductive tracks on a surface thereof.

26. The aerosol-generating device according to claim 25, wherein the aerosol-forming substrate comprises one or more printed circuit boards.

27. The aerosol-generating device according to claim 25, wherein the aerosol-forming substrate comprises an intermediate layer arranged between the first outer layer and the second outer layer, preferably wherein the first and the second outer layers of the multilayer substrate are printed circuit boards.

28. The aerosol-generating device according to claim 25, wherein the first and the second outer layers of the multilayer substrate are printed circuit boards.

29. The aerosol-generating device according to claim 28, wherein the intermediate layer is a metal layer.

30. The aerosol-generating device according to claim 25,
further comprising the extended end portion of the aerosol-forming substrate,
wherein the extended end portion comprises a copper layer.

31. The aerosol-generating device according to claim 30, wherein the copper layer is an intermediate layer arranged between the first outer layer and the second outer layer.

32. The aerosol-generating device according to claim 25,
further comprising the extended end portion of the aerosol-forming substrate located adjacent the first portion or adjacent the second portion,
wherein the extended end portion extends beyond the first or the second portion over a distance of at least 10 millimeters.

33. The aerosol-generating device according to claim 25,
further comprising both the extended end portion of the aerosol-forming substrate and the metal backing layer,
wherein the metal backing layer is not provided on a surface of the second outer layer of the multilayer substrate in the area of the extended end portion.

34. The aerosol-generating device according to claim 25,
further comprising the metal backing layer,
wherein the metal backing layer is a steel layer.

35. The aerosol-generating device according to claim 25,
further comprising the metal backing layer,
wherein the metal backing layer has a thickness of between 0.1 millimeter and 0.5 millimeter.

36. The aerosol-generating device according to claim 25,
further comprising the metal backing layer,
wherein the metal backing layer comprises first and second individual metal plates.

37. The aerosol-generating device according to claim 25, wherein the first and the second portions of the aerosol-forming substrate are planar and are non-co-planar.

38. The aerosol-generating device according to claim 25, further comprising an aerogel layer arranged between the aerosol-forming substrate and a longitudinal center axis of the cavity.

39. The aerosol-generating device according to claim 25, wherein at least a portion of the aerosol-forming substrate is flexible.

40. The aerosol-generating device according to claim 39,
wherein the aerosol-forming substrate further comprises a third portion between the first and the second portion, and
wherein at least the third portion is flexible such that the first portion is moveable relative to the second portion.

41. The aerosol-generating device according to claim 25, further comprising a shielding plate configured to block electromagnetic radiation and being positioned externally to the cavity such that the sensor is arranged between a longitudinal center axis of the cavity and at least a portion of the shielding plate.

42. The aerosol-generating device according to claim 25,
wherein the cavity is defined by a housing of the device,
wherein a first portion of the housing is transparent to at least some of the wavelengths of the electromagnetic radiation emitted by the emitter, and
wherein the emitter is configured to emit the electromagnetic radiation into the cavity through the transparent portion.

43. The aerosol-generating device according to claim 25, further comprising a controller configured to:
receive signals from the sensor, and
determine material properties of the aerosol-forming substrate at least partially received in the cavity, or an aerosol-generating article comprising the aerosol-forming substrate, based on a measured intensity of the electromagnetic radiation received at the sensor.

44. An aerosol-generating system comprising the aerosol-generating device according to claim 25 and an aerosol-generating article comprising the aerosol-forming substrate.
